(19) United States
(12) Patent Application Publication
(10) Pub. No.: US 2024/0275119 A1
(43) Pub. Date: Aug. 15, 2024

(54) Method for removing unwanted etalon effect in semiconductor gain chip

(71) Applicant: Pavilion Integration Corporation, San Jose, CA (US)

(72) Inventors: Haiwen Wang, San Jose, CA (US); Ningyi Luo, San Jose, CA (US)

(73) Assignee: Pavilion Integration Corporation, San Jose, CA (US)

(21) Appl. No.: 18/294,885

(22) PCT Filed: Nov. 2, 2023
(86) PCT No.: PCT/IB2023/061032

§ 371 Date: Feb. 2, 2024

Related U.S. Application Data
(60) Provisional application No. 63/382,083, filed on Nov. 2, 2022.

(51) Int. Cl. H01S 3/08; H01S 5/04; H01S 5/06; H01S 5/14; H01S 5/34

(52) U.S. Cl. CPC H01S 3/08054; H01S 5/041; H01S 5/0604; H01S 5/14; H01S 5/3412

(57) ABSTRACT

Some semiconductor gain chips used for both optically pumped and electrically pumped semiconductor lasers contain transparent layers for cooling or other purposes. These layers may cause unwanted etalon effect if one or more of the transparent layers are inside the laser cavity. The present invention provides a way to remove such unwanted etalon effect, by angling the chip away from the beam axis, and dimensioning the elements of the chip, so that any etalon effect in the transparent layers is substantially avoided, while the etalon effect in the semiconductor gain structure is preserved.

The present application claims priority from U.S. patent application No. 63/382,083, filed Nov. 2, 202, which application is incorporated by reference for all purposes.

### BACKGROUND

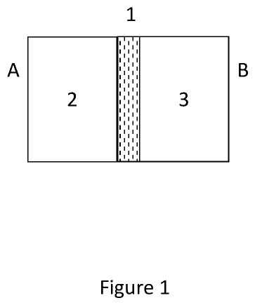

Semiconductor lasers are growing rapidly in recent years. FIG. 1 shows an example of a semiconductor gain chip. Item 1 in the center is a quantum well (QW) structure sandwiched between items 2 and 3, which are two transparent SiC (silicon carbide) layers, for cooling. Surface A of the gain chip is coated for high reflection of the lasing wavelength and anti-reflection of the pump wavelength. Surface B is antireflection coated for the laser wavelength.

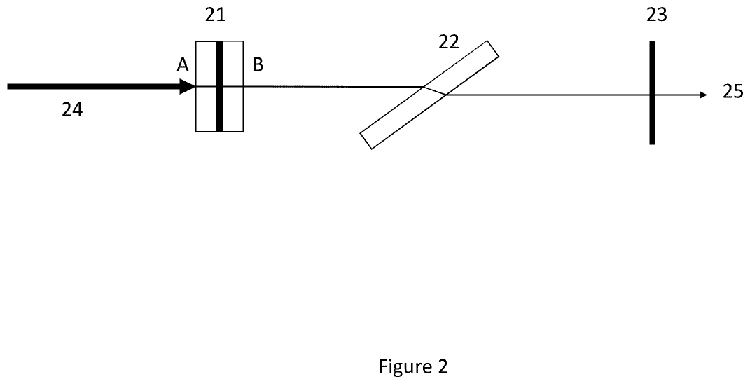

FIG. 2 shows a laser with such a QW gain chip. Item 21 is the QW gain chip and forms a laser cavity with item 23, which is the output coupler. Item 22 is a birefringent filter plate (BFP) positioned at the Brewster angle. Thus the laser lases in the p polarization. (It will be recalled that p-polarization is defined as polarization parallel to the plane of incidence, and that s-polarization is defined as polarization perpendicular to the plane of incidence. The light passing through the birefringent filter plate 22 is thus p-polarized.) Item 24 is the pump beam. Item 25 is the laser beam. Beam 25 defines a beam axis along which the beams travel during their interaction with the chip 21. It will be appreciated that to achieve the desired polarization, necessarily the beam axis is non-normal with respect to faces of the BFP 22.

Faces A and B of the chip 21 are parallel with each other, defining a facial plane of the chip 21. The alert reader realizes that the beam axis is normal to the facial plane of the chip 21, or said differently, the incident angle of the beam axis is at a right angle to the facial plane of the chip 21.

As will be discussed, the structure portrayed in FIG. 2 has the potential drawback that either or both of the transparent layers of the gain chip 21 can (undesirably) function as an etalon. The etalon effect of either or both of the transparent layers leads to undesirable results for the resulting lasing activity, as will be described.

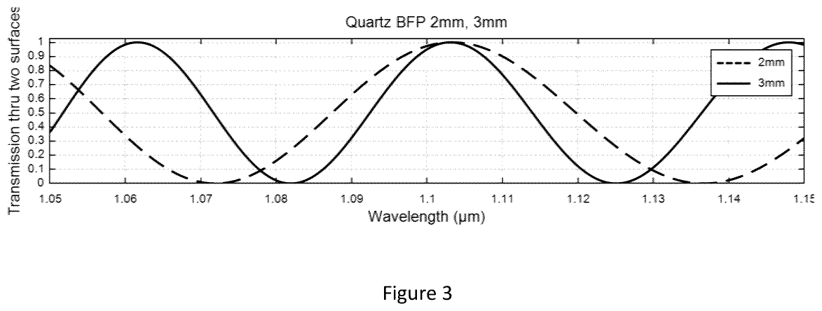

FIG. 3 shows the transmission curve of a BFP with two different thicknesses for a p-polarized beam. Its free spectral range is very wide so that adjacent transmission peaks are outside of the gain bandwidth of the semiconductor gain chip. The laser lases at the wavelengths around the transmission peak of the BFP.

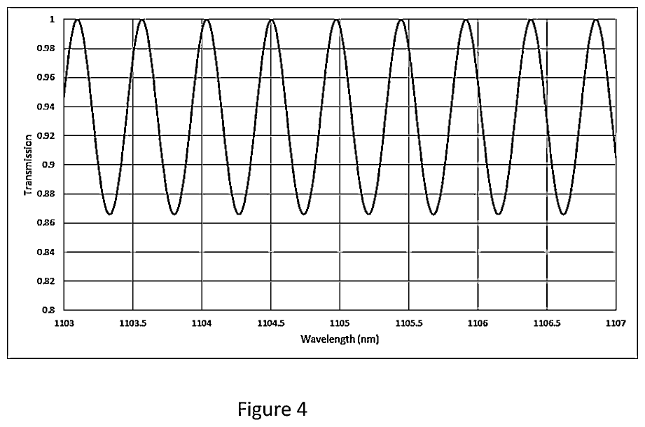

As just mentioned the surfaces of the SiC layers (items 2 and 3) are parallel. As such, the SiC layers act like etalons. FIG. 4 shows an example of the combined transmission curve of the two etalons assuming they are 0.5 mm thick. The etalon effect is sometimes unwanted. For example, lasing longitudinal modes may hop from one etalon transmission peak to an adjacent etalon transmission peak. One way to describe this is that there can be multi-longitudinal modes, and that the multi-longitudinal modes can interfere with each other. To the extent that such interference occurs, this makes the laser output noisy.

The present invention provides a way to eliminate the etalon effect from those transparent layers.

### DETAILED DESCRIPTION

Etalon effect is the result of the interference of the multi-reflected beams. For the etalon effect to cause harm, It requires substantial overlap among the multi-reflected beams. If the gain chip is tilted sufficiently with regard to the laser beam, the overlap among the multi-reflected beams is minimized. Therefore, the transparent-layer etalon effect would disappear. One cannot, however, simply impose some arbitrary degree of tilt in an effort to minimize the etalon effect from the transparent layers, because there is the risk of such a tilt degrading the otherwise very desirable QW effect of the QW structure. As will be described, it is only by careful attention to the dimensions of the various elements (for example the thickness of the QW layer and the thickness of each of the transparent layers) and also to the tilt angle, that one may achieve the results discussed below.

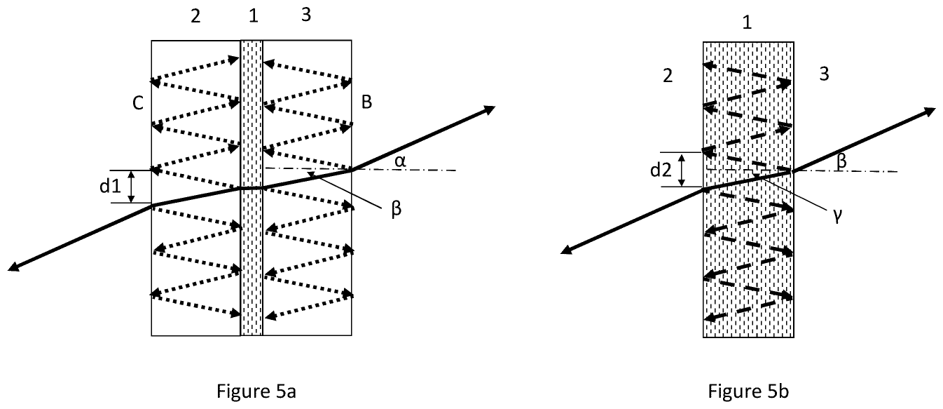

FIG. 5a shows a semiconductor gain chip that can be more conveniently configured to a tilted design. It has a QW structure 1 sandwiched between two transparent layers 2 and 3, in this example composed of SiC. Surface C of the gain chip is coated for anti-reflection of both the laser wavelength and the pump wavelength. Angles α, β, are beam angles in the air and in SiC, respectively. The dotted-arrow lines in FIG. 5a are multi-reflections in SiC.

The QW structure 1 of FIG. 5a is shown in more detail in FIG. 5b. Angle γ is the beam angle in the QW structure 1. The dashed-arrow lines are multi-reflections in the QW structure 1.

Some discussion of the dimensions involved in the semiconductor gain chip of FIG. 5a will be helpful. It will be appreciated that the thickness of SiC in each of the transparent layers 2 and 3 is usually at least two orders of magnitude greater than the thickness of the QW structure 1. Said differently, it is usually the case that each of the transparent layers 2 or 3 is more than a hundred times thicker than the QW structure 1. It will thus be appreciated that the portrayal in FIG. 5a is intentionally not to scale, so as to permit easy visualization of the optical paths involved in the (undesirable) etalon effect in the transparent layers 2 and 3 while also permitting easy visualization of the (desirable) multi-reflection paths within the QW structure 1.

An insight that makes the present invention possible is the realization that if one takes into account the dimensions involved, and the refractive indices of the materials involved, it is possible to select an angle β so that first and second things happen simultaneously. A first thing is that the (undesirable) overlap among the multi-reflections from the SiC (in the transparent layers 2, 3) is minimized. But the same time, the (desirable) overlap among the multi-reflections from the QW structure 1 is still good.

Stated plainly, if sufficient attention is paid to the dimensions and optical properties of the transparent layers 2 and 3, and of the QW structure 1, and if sufficient attention is paid to the selection of an angle β away from the normal direction, the SiC etalon effect disappears, while all or nearly all of the QW structure etalon effect is nonetheless preserved. There is little reflection loss at the interfaces between the SIC and QW structure because of the QW structure etalon effect.

For example, choose the thickness of the SiC to be 0.5 mm and the thickness of the QW structure to be 2 μm. (Another way to say this is that each of the transparent layers is 250 times thicker than the QW structure.) Choose the angle β to be 3°. For a laser at 1105 nm, the displacement d₁ between adjacent reflections in SiC is 52 μm. The overlap among the multi-reflections in SiC is thus minimized for a beam having a diameter on the order of 100 μm or less. (The two nearest reflections on either side of the center of the beam are thus 52 μm, and overlap of two adjacent reflections is significantly reduced since the beam is 2-dimensional.) There is thus no SiC etalon effect.

We can then turn to modeling of the (desirable) etalon effect within the QW structure. An exemplary QW structure is GaAs-based, in which case the angle γ is 2.3°. Given the distance between faces of the QW structure, the displacement d₂ between adjacent reflections in the QW structure is 0.16 μm. The (desirable) multi-reflections in the QW structure are still well overlapped despite the beam being tilted slightly relative to the normal. The (desirable) result is that the QW structure etalon effect is thus fully or at least largely preserved despite the beam angle being tilted slightly relative to the normal. (Beam angles and multi-reflection displacement in FIGS. 5a and 5b are exaggerated for easier visualization thereof.) A shorthand for this aspect of the invention is to say that we have a tilted gain chip.

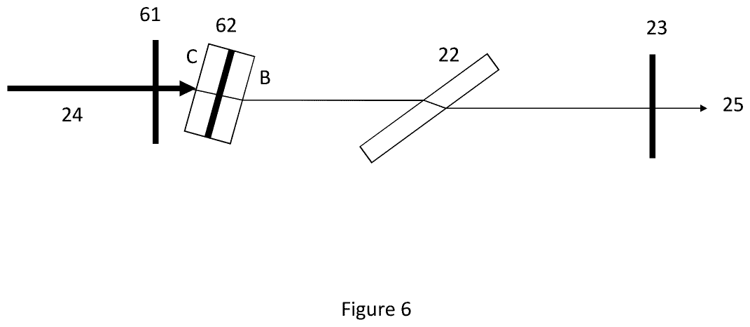

FIG. 6 shows a laser using such a tilted gain chip 62. The alert reader may closely compare the layout in FIG. 2 with the layout in FIG. 6, and will appreciate that the gain chip 62 in FIG. 6 is tilted from normal incidence of the light beams, while the gain chip 21 in FIG. 2 has its faces normal to the light beams. Item 61 is a mirror that reflects the laser beam and transmits the pump beam. Item 61 and item 23 (the output coupler) form the laser cavity. Item 62 is a gain chip such as the gain chip shown in FIG. 5, tilted at an angle so that SiC etalon effect disappears, while the QW structure etalon effect is fully or largely preserved.

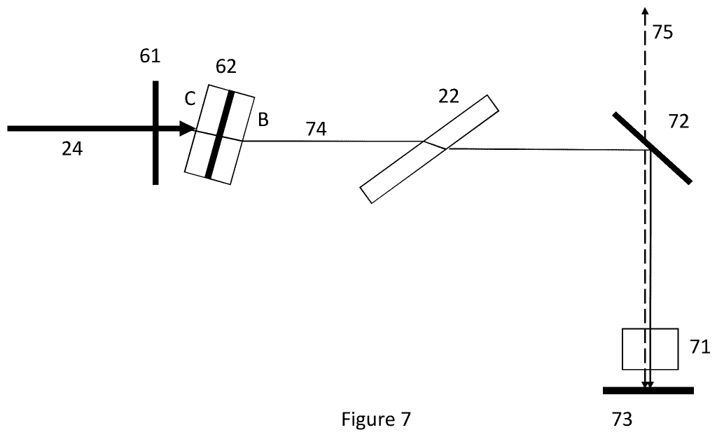

It will then be appreciated that the teachings of the invention offer their benefits not only in the simple laser of FIG. 6, but can also offer their benefits when the goal is to generate intracavity harmonics. FIG. 7 shows an example of intracavity second-harmonic generation. Item 71 is a nonlinear optic that generates the second harmonic (SH). Item 72 is a mirror that reflects the fundamental laser beam and transmits the SH. Item 73 is the end cavity mirror that reflects both the fundamental and the second harmonic beams. Item 74 is the oscillating fundamental beam inside the laser cavity defined by optical elements 61 and 73. Item 75 is the generated SH and is exits through item 72. Just as in the simpler laser shown in FIG. 6, the gain chip item 62 is tilted at an angle that is selected so that the SiC etalon effect disappears while, the QW structure etalon effect is preserved.

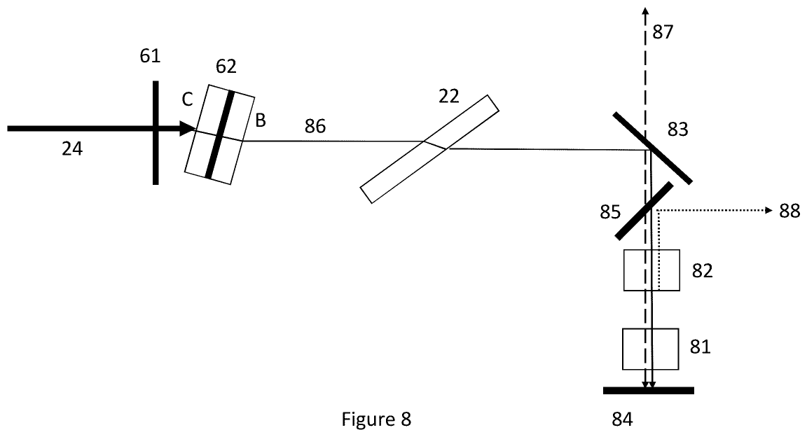

FIG. 8 shows an example of intracavity third-harmonic generation. Item 81 is a nonlinear optic that generates the second harmonic (SH), similarly to the function of item 71 in FIG. 7. Item 82 is a nonlinear optic that mixes the fundamental and second harmonic beams and generates the third harmonic (TH). Item 83 is a mirror that reflects the fundamental laser beam and transmits the SH. Item 84 is the end cavity mirror that reflects the fundamental and the second harmonic beams. Item 85 is a mirror that reflects the TH and transmits the fundamental and the second harmonic beams. Item 86 is the oscillating fundamental beam inside the laser cavity defined by optical elements 61 and 84. Item 87 is the SH and the residual SH is dumped through item 83. Item 88 is the output TH beam. Just as in the simpler laser shown in FIG. 6 and in the somewhat more complicated laser shown in FIG. 7, in this arrangement of FIG. 8, the gain chip item 62 is tilted at an angle that is selected so that the SiC etalon effect disappears, while the QW structure etalon effect is preserved.

Although a specific semiconductor gain chip design and transparent layer material as well as some specific laser designs are used to illustrate the present invention, the present invention is not limited to the specific semiconductor gain chip design, the specific transparent layer material, or the specific laser designs. The teachings of the invention offer themselves to obvious variants with respect to the specific semiconductor gain chip design, the specific transparent layer material, and the specific laser designs. It will also be appreciated that while the discussion above depicts the invention applied to optically pumped semiconductor lasers, the teachings of the invention can also offer themselves to other kinds of lasers such as electrically pumped semiconductor lasers. The alert reader will have no difficulty devising obvious variants and improvements upon the embodiments discussed herein, all of which are intended to be encompassed by the claims which follow.

1. A semiconductor laser comprising a semiconductor gain chip within a laser cavity, the laser cavity defining a beam axis, the semiconductor gain chip comprising a semiconductor layer defining a semiconductor gain structure with first and second faces, the semiconductor gain structure having an etalon effect, and a first transparent layer adjacent thereto on the first face thereof, the layers having respective faces, the faces of the layers defining a facial plane, the semiconductor gain chip being tilted from the beam axis, the tilt defining a tilt angle, tilt angle being selected such that the first transparent layer does not have an etalon effect, while the semiconductor gain structure etalon effect is preserved.

2. The laser of claim 1 wherein the laser is optically pumped.

3. The laser of claim 1 wherein the laser is electrically pumped.

4. The laser of claim 1, wherein the semiconductor gain chip is a quantum-well gain chip.

5. The laser of claim 1, wherein the semiconductor gain chip is a quantum-dot gain chip.

6. The laser of claim 1 wherein a second transparent layer is adjacent to the semiconductor gain chip on the second face thereof, whereby the second transparent layer likewise does not have an etalon effect.

7. The laser of claim 1, wherein the transparent layer material is SiC.

8. The laser of claim 1, wherein the transparent layer material is diamond.

9. The laser of claim 1 further comprising at least one one nonlinear optic disposed within the laser cavity, whereby intracavity harmonic generation occurs.

10. The laser of claim 9, wherein the intracavity harmonic generation is second-harmonic generation.

11. The laser of claim 9, wherein the intracavity harmonic generation is third-harmonic generation.

12. A method for use with a semiconductor laser comprising a semiconductor gain chip within a laser cavity, the laser cavity defining a beam axis, the semiconductor gain chip comprising a semiconductor layer defining a semiconductor gain structure with first and second faces, the semiconductor gain structure having an etalon effect, and a first transparent layer adjacent thereto on the first face thereof, the layers having respective faces, the faces of the layers defining a facial plane, the semiconductor gain chip being tilted from the beam axis, the tilt defining a tilt angle, tilt angle being selected such that the first transparent layer does not have an etalon effect, while the semiconductor gain structure etalon effect is preserved, the method comprising:
pumping the laser, whereby a laser beam is emitted from the laser, the beam substantially free of etalon effect from the first transparent layer.

13. The method of claim 12 wherein the laser further comprises a second transparent layer adjacent to the semiconductor gain chip on the second face thereof, whereby the beam is likewise substantially free of etalon effect from the second transparent layer.

14. The method of claim 12 wherein the pumping is optical pumping.

15. The method of claim 12 wherein the pumping is electrical pumping.
